(19) United States
(12) Patent Application Publication
(10) Pub. No.: US 2012/0049838 A1
(43) Pub. Date: Mar. 1, 2012

(54) Water quality indicator using light emitting diodes, rheostat and plug

(75) Inventor: Eberhard Essich, Cleveland, GA (US)

(73) Assignee: Eberhard Essich, Cleveland, GA (US)

(21) Appl. No.: 13/136,890

(22) Filed: Aug. 15, 2011

Related U.S. Application Data
(60) Provisional application No. 61/402,212, filed on Aug. 26, 2010.

(51) Int. Cl. G01R 31/00

(52) U.S. Cl. 324/96

(57) ABSTRACT

A novel electronic device is described herein that can be manufactured for a cost of less than $10.00, and that can be used by an inexperienced person to measure the TDS in an aqueous solution such as tap water and the conductivity/resistivity of a variety of other substances, materials, and liquids. A phono plug connected to the device is connected to a power source and is immersed in the aqueous solution and causes an LED (in one embodiment) to illuminate to an intensity directly proportional to the TDS in the solution. A rheostat connected to a second LED and power source is then adjusted until the second LED visually is equal in illumination intensity to the first LED. A number is then read from the dial of the rheostat, which number is directly proportional to the TDS of the aqueous solution (or material) and is used as data to compare to future or past readings or to determine the actual TDS using a chart or graph. Also, at least one electrical quantity can be determined, of any substance or material that can be brought into contact with, or into which the plug or any of the adapter leads of this device can be immersed, attached, affixed, contacted or or otherwise connected.

### CROSS REFERENCE TO RELATED APPLICATIONS

This application claims the benefit of the provisional patent application No. 61/402,212, filed Aug. 26, 2010

### FEDERALLY SPONSORED RESEARCH

Not Applicable

### SEQUENCE LISTING

### Not Applicable

### BACKGROUND

This invention relates to water quality indicators used to test and monitor water quality and that can measure total dissolved solids (TDS), and electrical conductivity, and can be used to measure skin conductivity of human skin (as does a polygraph), conductivity of saliva and other body fluids, conductivity or TDS of fruits, vegetables and other plant fluids, chemical reaction rates, and can detect audio output of amplifiers and like devices. With appropriate simple off the shelf adapters at least one of several electrical properties of the heart and other materials and substances can be measured as well. While teaching biology laboratories I searched catalogs, stores, the internet and other sources and found there was no inexpensive tool or device available to measure the changes taking place in water during plant metabolism, for example carbon dioxide utilization. Also, when testing water for the public I found there is no truly inexpensive and reliable way to test their water for quality between the water tests they hired a laboratory or consultant to do. Total Dissolved Solids (TDS) is one of two tests designated by the USEPA (United States Environmental Protection Agency) to be a recommended annual test of well water. It is well known and accepted in the scientific community that TDS is a measure of the conductivity and/or resistivity of a substance under defined conditions. This device can be used to measure conductivity of water but I was surprised to find that this device could also be used to measure all sorts of other materials, substances, and solutions as well as water.

### OBJECTS AND ADVANTAGES

I thought that it would be useful to have a small, portable, manually operated, rugged, inexpensive electronic device available for students/teachers and consumers to use to measure TDS in aqueous solutions. It should also not be subject to the usual electromagnetic and electromechanical disturbances that quartz and liquid crystal devices and others demonstrate and it should have long battery life and easily interchangeable parts so as to be inexpensive to operate and maintain and one for which a variety of adapters is readily available with which to allow testing of other substances. This device meets all these criteria and moreover can be used to measure all sorts of other materials and solutions for conductivity. This unexpected outcome is one reason why the device is so useful in the teaching laboratory. This device will cost less than $10.00 (2010 US Dollars), has no expensive and fragile gauges, meters, LCD's (liquid crystal display) panels or other displays with limited life or that may be easily damaged and difficult to read under low light conditions, allows for individual components to be replaced, uses only two lamps (LED's light emitting diodes), a rheostat, several resistors and a phono plug (or similar power plug or other suitable plug or device) to obtain a TDS reading, will withstand substantial physical abuse and will last a lifetime if properly used. Furthermore, it can be used to determine the presence or absence of water, the height of a water column, dissolved chemical levels including carbon dioxide levels in pure water, and other parameters. Standard adapters and electrical cords can be used to extend the distance between sample and device to reach areas that are hard to access. The device can also be plugged directly into the output of an audio device to test for the presence of voltage or current. This is the only water quality indicator that uses LED's, which are known for extreme durability, long life and low power consumption, a simple plug and a rheostat, which are also known for long term reliability and accuracy respectively, to provide data on water quality of any kind and various additional other substances using simple over-the-counter adapters. It is therefore a unique and very inexpensive design. Distilled water, spring water, tap water, sea water and others can all be measured using this device. Since it provides data on invisible water quality parameters it can warn the user of dangerous changes in the quality of their water. For example, arsenic, lead, mercury and other substances can be detected using the WQI but cannot be detected visually or by taste or by smell. The WQI is especially sensitive to changes in distilled and deionized and reverse osmosis treated water and is an excellent way to determine whether or not a distillation apparatus or a reverse osmosis filter is working properly. Fruits, vegetables skins and contents, saliva, human skin conductivity (and therefore heart beat, perspiration, and other parameters); conductivity of metals, plastics, graphite, and many more substances and materials can be measured using this device.

This device would be exceptionally useful in the field of teaching because it has so many potential uses for various experiments conducted in a teaching lab. It will be extremely useful to the average consumer because it is so simple to operate, inexpensive, rugged in design, and will answer relevant questions about the consumer's water quality. Home owners, RV (recreational vehicle) owners, boat owners, campers and others will benefit from being able to monitor their water quality for virtually no cost, as often as they wish every day.

Much more sophisticated devices are available but they are more expensive and out of reach for the average consumer. Most require standardization with special reagents that the average user cannot obtain. None of them can measure the conductivity/resistivity of substances, materials, or solutions other than water. The cheapest such devices sell for over $30.00 and the most expensive are in the $1,000.00 range, and they do not provide significant advantage to the average user. Our device overcomes these problems by using inexpensive yet very reliable electronic components that produce very repeatable results and are not complex enough in structure to create interfering interactions between components. Secondly, it will be less than $10.00 (2010 US Dollars) to purchase. In addition, these more expensive devices cannot be used to measure conductivity of substances other than water or aqueous solutions and use very large probes. Our device can be used to measure skin conductivity, plant and animal fluids extracted or in situ (ex touching the phono plug to saliva in the mouth will give a conductivity reading without harming the individual, pressing the phono plug to the skin will give a conductivity reading of the skin surface without any damage or pain, inserting the phono plug or an appropriate adapter which can be used with the phono plug and WQI, into a fruit, vegetable or other semisolid substance will provide a reading as well. In the past there has been no good inexpensive way to measure the conductivity of clay and the like in a student laboratory and then to plug the same device into a phono jack to detect the presence or absence of some electrical property in that electronic device. This would be of interest to science students and teachers as well as engineers, dieticians, chemists and others. Many of the existing water quality indicators or water quality monitors (U.S. Pat. No. 4,849,098, Continuous Water Quality Monitor Wilcock et al 1989, and U.S. Pat. No. 4,708,791, November 1987, Dillard; and more recently U.S. Pat. No. 6,936,160 B2, Moscaritolo et al, August 2005, U.S. Pat. No. 5,580,444, December 1996 Burrows and related patents;) are installed into a system that purifies water. As such, these WQI's are not portable and cannot be used to measure anything but the water in the system where they are installed. Our device overcomes this problem because it is portable and can be adapted to a plurality of uses and can measure a multitude of different compounds, substances, and materials using a multitude of different and simple and readily available adapters where appropriate. It will fit into a shirt or pant pocket and easily into the hand of a user, from child to adult. U.S. Pat. No. 4,708,791, November 1987 teaches a device that requires an amplifier to amplify the difference between two voltages. Our device not only does not require such an amplifier, but would not function properly if an amplifier were incorporated into the design. As a result we do not use a flip-flop of any kind, but rather a continuous spectrum of illumination intensities of a single LED compared to a second LED which intensity is fixed by the total dissolved solids concentration in the solution. Flip- flop between two different LEDs of different colors, only gives information about one of two states, “acceptable” or “unacceptable” levels of solids in the water. Our device allow continuous measurements for the entire potential concentrations/spectrum of dissolved solids in a solution and will provide data that can be converted directly into total dissolved solid values for the entire spectrum from a reading of 0 ppm (parts per million) TDS to >2000 ppm TDS. Furthermore the device described in the patent (U.S. Pat. No. 4,708,791) is fixed into a pipe and is not portable. Also, it is lacking a rheostat and therefore must be preset to a specific range of TDS values. Our device overcomes this deficiency by providing a rheostat that can be adjusted and thereby provide useful results over the complete range of TDS readings in a given sample solution.

U.S. Pat. No. 4,849,098 also describes WOM (water quality monitor) that is an integral part of a filtration system and as such is not portable. Our device is easily portable to any location. It is handheld and can therefore be used to measure environmental samples such as streams, lakes, the ocean, springs, wells and other waters that cannot be measured with a non-portable device or a portable device that is large and cumbersome.

U.S. Pat. No. 4,708,791 describes a water quality monitor that requires a dip switch and an amplifier as part of the circuitry and has only two outputs. Either a red LED lights indicating excessive solids or a green LED lights indicating acceptable levels of solids. Our device has no requirement for signal amplification and therefore does not require an amplifier. Nor does it require and dip switch to adjust the device to the proper range of dissolved solids. Instead it operates without amplification and automatically adjusts to any range of dissolved solids in the solution with very simple circuitry. In addition, if more accurate readings are desired, dilution of the original sample with a 10 fold volume of distilled water will produce highly accurate and repeatable results in the most sensitive area of the instrument's range. The instrument as is has a range, and can read values of dissolved solids from zero to thousands of parts per million of TDS and as such can read in the entire range of what is normally found in tap water, well water, springs, the ocean, and most other natural or man-made sources of water including deionized, reverse osmosis treated, distilled and filtered waters. In addition, the instrument provides actual values as outputs rather than just acceptable or unacceptable levels of solids. It provides numerical data that can easily be converted to the entire range of actual TDS values using a table, chart, or equation. Our device also does not have any need for a “push to test” button because the function of the LED's themselves indicate the battery condition and readiness of the circuit. If LED intensity becomes too dim to observe, then the battery must be replaced. Otherwise, the device can be safely used and is reliable.

Further objects and advantages of this invention will become apparent from a consideration of the drawings and ensuing description.

### DRAWINGS

FIG. 1: Water Quality Indicator Circuits

FIG. 2: Water Quality Indicator Enclosure isometric view

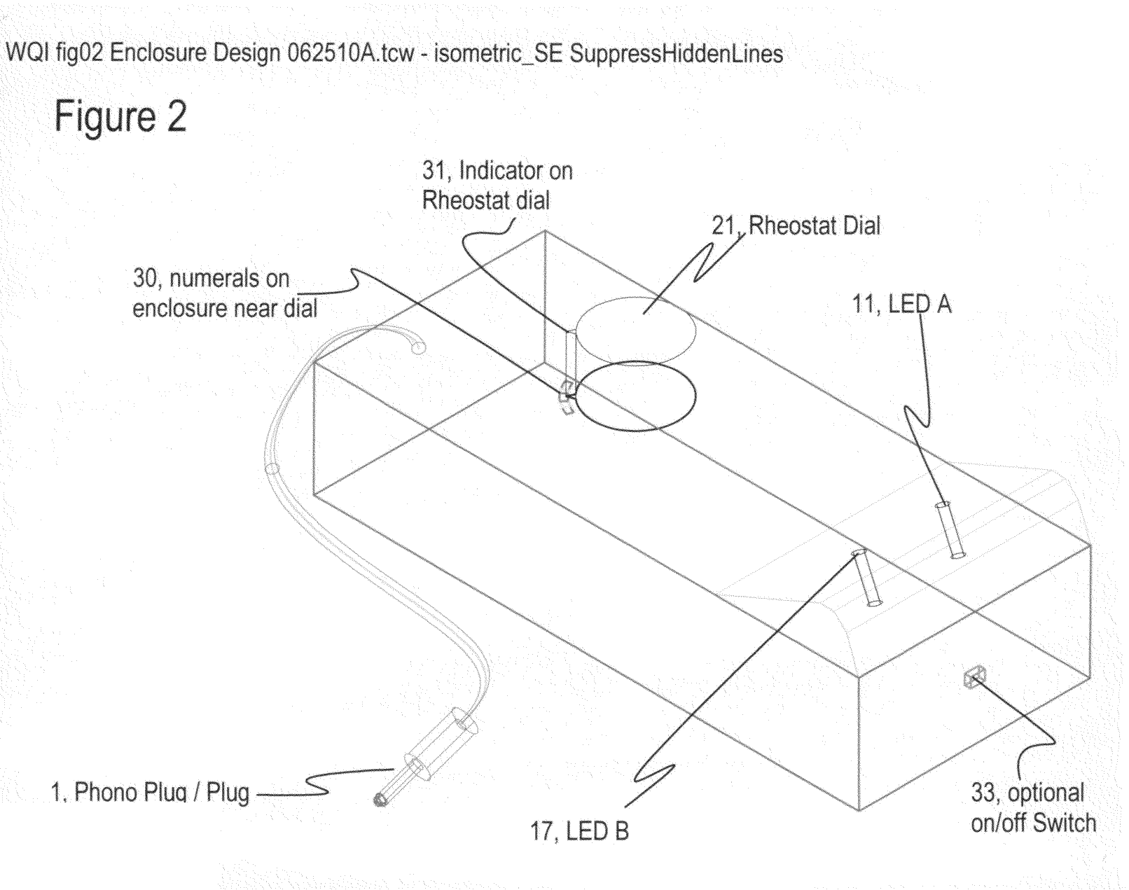

FIG. 3: Water Quality Indicator Enclosure solid view

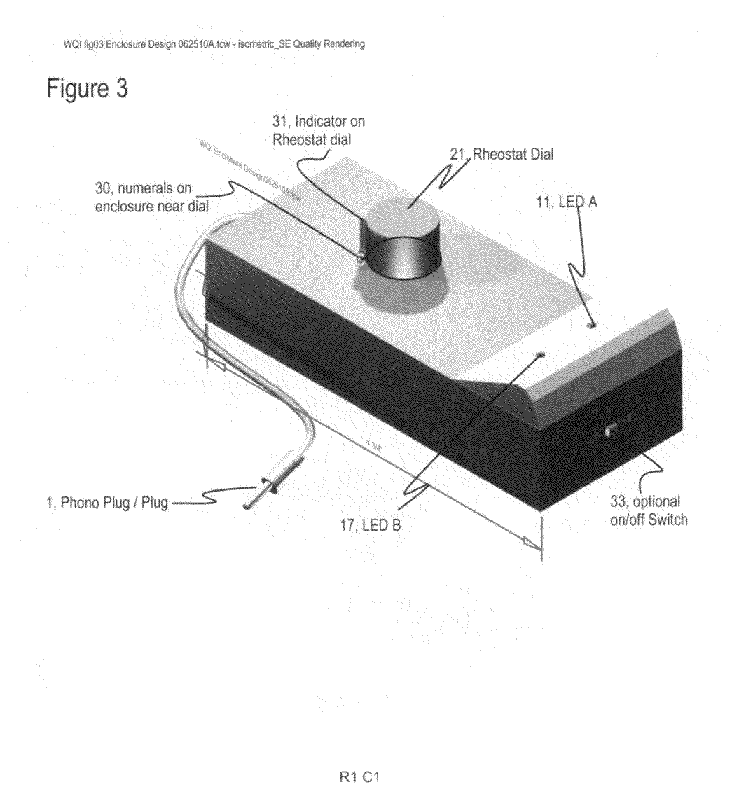

FIG. 4: Various adapters that are readily available and can be used with the WQI

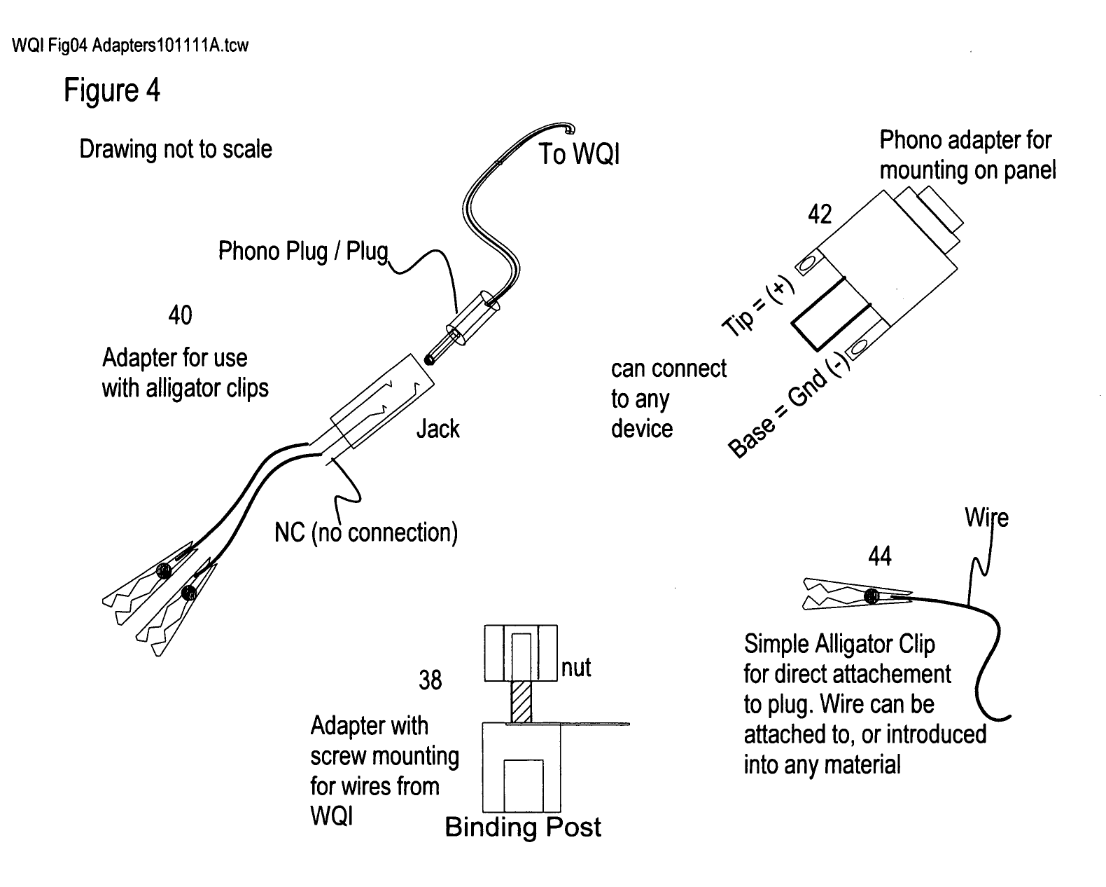

FIG. 5: Flow Chart of a Method of Use of WQI

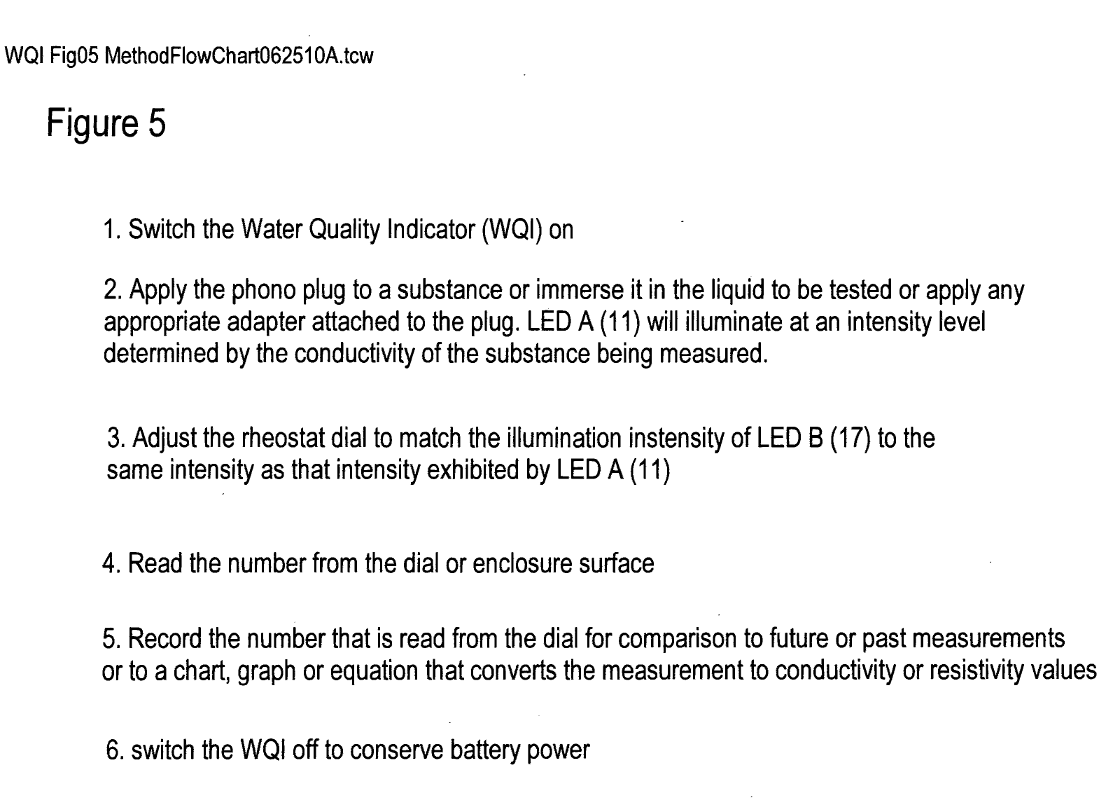

### DESCRIPTION

Following is a description of one preferred embodiment of this invention, which we will call the WQI (water quality indicator). It will be obvious to one skilled in the art from the schematic and description, how to construct such a device and that a variety of alternative embodiments are possible. Alternative embodiments (even those not described explicitly herein) that provide the same function with similar components should be considered to be within the scope of this invention.

This is a hand-held, electronic device which may be powered by an internal 9V (Volt) power source and can be used to measure the level of dissolved solids in an aqueous solution, for example water or the amount of conductivity and resistance in or on a substance, ex a fruit, vegetable or human skin or saliva, without significant damage and without pain or danger to health.

One configuration of the instrument may have an on-off switch (33) to save battery power and if properly used a 9V battery (27) is easily replaced and will have a life expectancy of 5 years or more. Any other power source (27) that can be adjusted to 9 V will do. The device will be easily affordable by an average consumer and can cost less than $10.00 (US Dollars in year 2010).

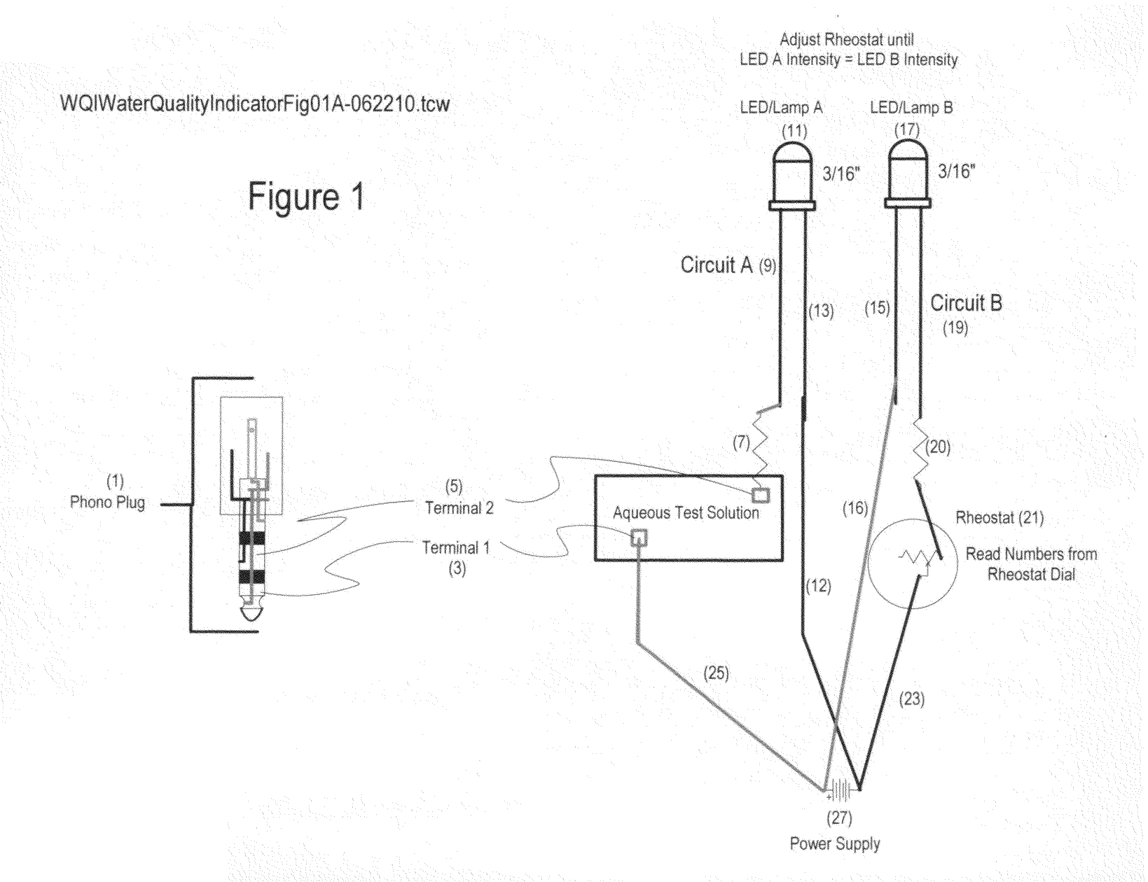

One circuit of the device (FIG. 1, 19; circuit B of the device) consists of connections from one terminal of the battery (FIG. 1, 27) through a conductor (FIG. 1, 23) to the rheostat (FIG. 1, 21) then through a low voltage resistor (FIG. 1, 20) to the appropriate lead of an LED (light emitting diode) (FIG. 1, 17; lamp B) then proceeding through the second lead of the LED (FIG. 1, 15) through a conductor (FIG. 1, 16) back to the second terminal of the battery (FIG. 1, 27), circuit complete. In one embodiment the lamp is an LED and is red, but any kind of appropriate low voltage lamp and lamp color will do. It is preferable however, that whatever the color is chosen for one LED, for example lamp B, that the same color be chosen for the second LED (In this example lamp A uses the same color as lamp B) so as to make intensity comparisons easier and more useful. This circuit (circuit B) allows for LED B to be adjusted to any light intensity from off to maximum intensity produced by the circuit. If resistor 20 is 330 ohms, then the LED will reach the maximum allowable intensity but prevent burnout of the LED. When a given intensity is observed in lamp A (FIG. 1, 11), lamp B (FIG. 1, 17) can be adjusted with the rheostat to match its intensity to that observed in lamp A. The intensity of illumination of lamp A (FIG. 1, 11) is determined by the conductivity of the test substance or material as follows. Circuit A, the second circuit in the device, also begins with one terminal of the battery (FIG. 1, 27) and connects via a conductor (FIG. 1, 12) to one lead (FIG. 1, 13) of LED A (FIG. 1, 11, lamp A), then passes through the second appropriate lead of LED A (FIG. 1, 9) through a resistor (FIG. 1, 7) which may, but does not need to be, of the same resistance as resistor 20 (FIG. 1, 20), and to one terminal (FIG. 1, 5; terminal 2) of a phono plug, or like detector. The test solution or material separates terminal one from terminal two by a distance determined by the specifications of the phono plug. The second terminal (FIG. 1, 3; terminal 1) also makes contact with the test solution or material and through a conductor (FIG. 1, 25) completes the circuit to the second terminal on the battery. As such, and in this configuration the conductivity of the test solution or material will determine how much electricity passes through to the battery and thus determines directly, the intensity of LED A (FIG. 1, 11). For example, if the test material is copper or an aqueous solution with very high salt concentration, then more current will pass through the solution, and LED A will illuminate with high intensity. On the other hand if the test material or solution were wood, or pure distilled water respectively, very little, if any current would pass through the material or solution and the LED A would not light at all or light very dimly. In either case, adjustment of the rheostat (FIG. 1, 21) will bring the intensity of LED B (FIG. 1, 17) to match the intensity of LED A and different numbers will therefore be indicated by the rheostat dial. Each of those numbers will correspond to a specific conductivity value and can therefore be used to compare one material or solution to another material or solution, or give precise conductivity values for each of the materials or solutions.

One method is as follows:
a. Switch the WQI on
b. Apply the phono plug to the substance or immerse it in the aqueous solution liquid to be tested or apply any appropriate adapter attached to the phono plug to the substance or immerse it into the liquid which is to be tested. LED A will illuminate to a level determined by the substance being measured
c. Adjust the rheostat dial to match the illumination intensity of LED B to the same intensity as that exhibited by LED A
d. Read the number from the dial or enclosure surface
e. Record the number that is read from the dial for comparison to future or past measurements or to a chart, graph or equation that converts the measurement to conductivity or resistivity values
f. Switch the WQI off to spare battery power

What I claim as my invention is:

1. A device for testing and monitoring at least one electrical property of a material or solution comprising:
a. a lamp (LED in one preferred embodiment) configured to communicate by illumination intensity of the lamp, the quantity of current going through the phono or electrical plug or other contacting element, said current passing from one terminus of the phono or electrical plug to a second terminus on the phono or electrical plug through a material or solution
b. a second lamp (LED in one preferred embodiment) configured to communicate by illumination intensity of the lamp, the quantity of current going through an adjustable rheostat, by direct connection via conductive material to said rheostat, the lamp, a resistor and the current source
c. a phono or electrical plug, or other appropriate device with at least two termini configured for introduction into, or application onto, the test material
d. a power source configured to provide electrical current to the two termini of a phono or electrical plug, and a rheostat, and the lamps (LED's in one preferred embodiment)
e. an adjustable rheostat configured with user input coupled to and for controlling the current going through the second lamp configured to change the illumination intensity of said lamp as adjustment is made to the rheostat
f. a non-conducting enclosure
g. a pattern of numbers or colors positioned adjacent to the rheostat dial on the enclosure so a pointer on the rheostat dial can indicate a single number or color at any given level of electrical conductivity
h. various conducting elements to interconnect the various electronic components described
i. an arrangement of components such that two (2) independent circuits exist
j. an arrangement of components such that one independent circuit with a rheostat controls the light intensity of one LED
k. an arrangement of components such that a second independent circuit produces a light intensity in the second LED which reflects directly the conductivity of the test material

2. The device of claim 1, wherein the power source includes at least one of the following: a battery and an external power source.

3. The device of claim 1, wherein the dial of the device may be used to store at least one datum

4. The device of claim 1 in which the lamp includes at least one light emitting diode (LED)

5. The device of claim 1, wherein the device may be configured for remote operation via wired or wireless communication between the LED's and the phono or electrical plug

6. The device of claim 1, wherein the device is constructed to be portable or to be connected to a fixed material, substance or solution

7. A method for testing the purity of an aqueous solution or test material, comprising:
a. Turning the hand held device on using an on/off switch
b. Introducing of the phono or electrical plug to the aqueous test solution and observing the intensity of illumination of a first LED
c. Adjusting the rheostat, which controls current to a second LED to match the light intensity of a second LED to the first LED which light intensity is determined by the amount of current conducted through the test material or aqueous solution and thus its total dissolved solids and purity
d. Manually reading and recording the number opposite the pointer on the rheostat as a measure of the purity of the test material or aqueous solution
e. Turning the water quality indicator off using an on/off switch

8. A device for measuring total dissolved solids and at least one electrical property of a material or aqueous solution using illumination intensity of LED's as data indicators

9. The device of claim 8, wherein the device is handheld and portable or may be connected to a fixed material, substance, or solution reservoir

10. The device of claim 8, wherein the device can be used in total darkness and the values stored in the dial position until illumination is available for reading

11. The device of claim 8, wherein the device can store data in the dial position

12. A system for determining impurities in a tested substance by means of at least one electrical property of the test material and substance using the devices and methods described in claims 1 and 8
